(19) United States
(12) Patent Application Publication
(10) Pub. No.: US 2007/0218692 A1
(43) Pub. Date: Sep. 20, 2007

(54) Copper-based metal polishing compositions and polishing processes

(75) Inventors: Jonathan J. Wolk, Bethel, CT (US); Walter A. Wolk, Bethel, CT (US)

Correspondence Address: OLIFF & BERRIDGE, PLC, P.O. BOX 19928, ALEXANDRIA, VA, 22320, US

(73) Assignee: Nissan Chemical Industries, Ltd., Tokyo (JP)

(21) Appl. No.: 11/488,682

(22) Filed: Jul. 19, 2006

Related U.S. Application Data
(60) Provisional application No. 60/763,358, filed on Jan. 31, 2006.

(51) Int. Cl. C09K 13/00; H01L 21/461; B44C 1/22; H01L 21/302; C03C 15/00

(52) U.S. Cl. 438/692; 252/79.1; 216/88; 216/89

(57) ABSTRACT

A copper-based metal polishing composition includes abrasive particles, a borate, an oxidizing agent, and water. A process for polishing a semiconductor substrate includes positioning the semiconductor substrate; polishing the positioned semiconductor substrate with a first polishing composition including abrasive particles, an ammonium borate, an oxidizing agent, and water, and having a pH of from 6.5 to 9; and further polishing the polished semiconductor substrate with a second polishing composition including abrasive particles, a potassium borate, an oxidizing agent, and water, and having a pH of from 7 to 10.

### CROSS-REFERENCE TO RELATED APPLICATION

This non-provisional application claims the benefit of U.S. Provisional Application No. 60/763,358, filed Jan. 31, 2006. The disclosure of the provisional application is incorporated herein by reference in its entirety.

### BACKGROUND

Recent trends toward higher integration and higher performance of semiconductor integrated circuits have necessitated development of new precision processing techniques. Chemical mechanical polishing (CMP) is one of the precision processing techniques under development. CMP is often employed during fabrication of semiconductor integrated circuits. For example, CMP may be employed in planarizing interlayer insulating films, forming metal plugs, and forming inlaid and multi-layer interconnect (wiring) structures.

To improve performance of semiconductor integrated circuits, copper and copper alloys have been considered as materials for use as interconnect structures. Copper and copper alloys present difficulties in fabrication because, for example, unlike aluminum alloys, it is difficult to conduct precision processing of copper and copper alloys by dry etching. As an alternative to dry etching, a damascene process may be employed. In a damascene process, a semiconductor substrate having an insulating film formed thereover is etched to form a trench. A film of the copper or copper alloy is formed over the substrate so as to fill the trench. The film of copper or copper alloy, except for the portion in the trench, is removed by CMP to leave an interconnect structure inlaid into the semiconductor substrate.

In a typical CMP process, a semiconductor wafer is mounted on a wafer carrier in opposition to a polishing pad that is attached to a polishing platen. The polishing platen is rotated at a predetermined velocity. The wafer is then pressed into contact with the polishing pad at a predetermined pressure and rotated at a predetermined velocity. A polishing composition, or slurry, is supplied to the interface between the wafer and the polishing pad to create a liquid chemical/abrasive film. The polishing composition flows between the wafer surface and the polishing pad, and a chemical component of the polishing composition converts a surface of a metal film on the wafer into an easily abraded species. An abrasive component including a sub-micron sized metal oxide of aluminum, cerium or zirconium abrades away the easily abraded species.

Polishing compositions for use in CMP may include various ingredients, such as oxidizing agents, solid abrasive particles, dissolving agents and protective film-forming agents. It has been suggested that CMP removes topographical features of a metal film by oxidizing the film to form a metal oxide on its surface and abrading away the metal oxide with abrasive particles. Because a polishing pad is substantially planar, only topographical features of the metal film are removed by the abrasive particles—the polishing pad does not reach into trenches in the metal film.

At the conclusion of a CMP planarization process, deposited metal films should be flattened so as to be coplanar with the etched surface of the substrate. This configuration permits the metal to function as interconnect wiring connecting devices and transistors. A flat, precision surface further allows multi-level vertical integration of interconnect structures necessary for fabricating complex integrated circuits. Multi-level vertical integration of interconnect structures is accomplished by performing precise lithographic/deposition techniques after the CMP planarization process is complete. If a flat, precision surface is not achieved after performing CMP planarization, the above-mentioned lithographic/deposition techniques cannot be properly performed, and multi-level vertical integration of interconnect structures cannot be achieved. That is, any defect or combination of defects created during CMP planarization can cause a multi-level integrated structure to fail or to perform deficiently, e.g., by increasing resistance to voltage.

Defects commonly associated with CMP planarization processes include topography defects and light-point defects. Topography defects, which may be measured using advanced profiling analysis, include dishing, erosion and thinning. Dishing is the inadvertent removal of inlaid metal from an etched portion, or trench, in a substrate. The problem of dishing arises from the fact that different thin films, adjacent to one another, polish at different rates. In a damascene process, dishing refers to the thinning of the center of metal wiring. In damascene, it is important to control the amount of dishing because dishing may decrease conductivity. The amount of dishing depends on a width of wiring grooves, elasticity of a polishing pad, slurry characteristics, polishing conditions, and an amount of over-polishing. During copper-based metal CMP, for example, copper structures are planarized followed by bulk copper removal. Next, an over-polish step may be performed to address areas where copper has not yet been cleared. Such areas may remain because polishing may not be performed uniformly and/or an original thickness of deposited copper may not be uniform. Over-polishing may result in “dishing” of copper because a slurry removes copper faster than the slurry removes, for example, a tantalum barrier layer.

Erosion is the inadvertent removal of portions of a substrate adjacent to inlaid metal. Thinning is the unwanted removal of both substrate and inlaid metal causing a thinner than desired composite layer. Light point defects, which may be measured using laser or optical defect analysis, include scratching, staining, residual particles, residual metal and corrosion. Scratching is the formation of gouges or scrapes in a polished surface. Staining is the incomplete oxidation of a film leaving a poor surface finish. Residual particles are small objects attached to a substrate surface after CMP planarization is complete. Residual metal describes metal particles or metal “puddles” remaining on a substrate surface where metal should not be inlaid. Corrosion is the severe oxidation of a metal film apparent as pitting, dark staining or elimination of metal from an inlaid portion of a substrate. Each of these defects can adversely affect the electrical characteristics and connectivity of a resulting device.

Various attempts have been made to obtain polishing compositions that can be used in CMP planarization processes for copper-based metals while avoiding the various defects outlined above. For example, JP 2004/006810 discloses polishing compositions for copper-based metals including a condensed phosphoric acid or a salt of a condensed phosphoric acid, an oxidizing agent such as hydrogen peroxide, abrasive particles, and a reaction inhibitor such as benzotriazole. JP 2004/103667 discloses polishing compositions for metals including a condensed phosphate, a periodate, abrasive particles, and a reaction inhibitor. WO 01/21724 discloses polishing compositions for copper- or tungsten-based metals including a buffer that maintains a pH of between 3 and 10 and an oxidant reacting with the metals.

U.S. Pat. No. 6,705,926 discloses polishing compositions including an abrasive, a carrier, and either boric acid or a conjugate base thereof. U.S. Pat. No. 5,575,885 discloses polishing compositions for copper-based metals including an organic acid selected from aminoacetic acid and amidosulfuric acid, an oxidizer and water. U.S. Pat. No. 5,800,577 discloses polishing compositions for metals including a carboxylic acid, an oxidizing agent, and water, a pH of the polishing compositions being adjusted to between 5 and 9 with an alkali.

### SUMMARY

In various exemplary embodiments, copper-based metal polishing compositions and copper-based metal polishing processes are provided. Polishing compositions and processes according to the present invention provide superior defect resistance relative to known polishing compositions and processes. Polishing compositions according to the present invention have anti-scratching and anti-dishing properties. In particular, polishing compositions according to the present invention can reduce and/or prevent dishing of a copper layer in a first polishing step and can reduce and/or prevent dishing of a barrier (e.g., tantalum) layer in a second polishing step.

In various exemplary embodiments, copper-based metal polishing compositions include abrasive particles, a borate, an oxidizing agent, and water.

In various exemplary embodiments, copper-based metal polishing compositions include abrasive particles, an ammonium borate, an oxidizing agent, and water. In some such embodiments, the polishing compositions have a pH of from 6.5 to 9, the pH being adjusted by addition of ammonium hydroxide to the polishing composition.

In various exemplary embodiments, copper-based metal polishing compositions include abrasive particles, a potassium borate, an oxidizing agent, and water. In some such embodiments, the polishing compositions have a pH of from 7 to 10, the pH being adjusted by addition of potassium hydroxide or ammonium hydroxide to the polishing composition.

In various exemplary embodiments, processes for polishing a semiconductor substrate include positioning the semiconductor substrate, a surface of the semiconductor substrate having a barrier layer formed thereon and the barrier layer having a copper layer formed thereon. Exemplary processes further include polishing the positioned semiconductor substrate with a first polishing composition, the first polishing composition comprising abrasive particles, an ammonium borate, an oxidizing agent, and water, the first polishing composition having a pH of from 6.5 to 9, the pH being adjusted by addition of ammonium hydroxide to the first polishing composition. Exemplary processes also include further polishing the polished semiconductor substrate with a second polishing composition, the second polishing composition comprising abrasive particles, a potassium borate, an oxidizing agent, and water, the second polishing composition having a pH of from 7 to 10, the pH being adjusted by addition of potassium hydroxide or ammonium hydroxide to the second polishing composition.

These and other optional features and possible advantages of various aspects of this invention are described in, or are apparent from, the following detailed description of exemplary embodiments of products and processes that implement this invention.

For a better understanding of the invention as well as other aspects and further features thereof, reference is made to the following drawing and descriptions.

### BRIEF DESCRIPTION OF THE DRAWING

Exemplary embodiments of the invention will be described in detail with reference to the following figure wherein:

FIG. 1 is schematic depiction of a patterned wafer showing the phenomenon of dishing, which may result from CMP and which can be reduced and/or prevented by employing exemplary polishing compositions according to the present invention.

### DETAILED DESCRIPTION OF EMBODIMENTS

In various exemplary embodiments, the present invention is directed to processes for conducting CMP of a substrate. In embodiments, processes according to the present invention involve conducting CMP planarization in two or more stages to obtain flat, planar surfaces having minimal defects. In particular, such planar surfaces may comprise a patterned surface of insulating and conductive material that may function as a series of interconnect structures (wiring), upon which additional layers of vertical interconnect structures may optionally be formed. After CMP planarization is conducted using processes according to the present invention, it is possible to proceed successfully with additional processing of the substrate to obtain a functioning device. In various exemplary embodiments, different polishing compositions (or slurries) having different chemical compositions are used in each of the two or more stages of the processes according to the present invention.

Exemplary processes are applicable for performing copper-based metal CMP, i.e., CMP performed to remove and/or planarize a copper or copper species film formed on a substrate. In particular, exemplary processes are suitable for removing and/or planarizing a copper or copper species film formed over a barrier layer, which in turn is formed over a semiconductor substrate. In embodiments, processes according to the present invention may be used to planarize a copper or copper species film formed on a tantalum or tantalum nitride barrier layer, which in turn is formed on an insulating layer of a silicon substrate.

An exemplary context to which processes according to the present invention may be applied is described as follows. A semiconductor substrate having an insulating layer may be patterned using, e.g., lithographic techniques, and the patterned substrate may be etched. After etching, a barrier layer may be formed over the etched substrate. After formation of the barrier layer, the etched areas, or trenches, in the substrate my then be filled with copper, for example by chemical vapor deposition or electroplating. Due to limitations of known techniques for filling trenches in a substrate with copper, in addition to filling the trenches, a copper layer is formed over an entirety of a surface of the substrate. The topography of the copper layer corresponds to the topography of the semiconductor substrate before application of the copper. That is, copper is present in step-like structures rising above the adjacent trenches in the surface of the substrate, which have been filled with copper. The copper steps may have heights of from about 4,000 to about 10,000 angstroms relative to a top surface of the adjacent interconnect structures.

Various exemplary embodiments of the processes according to the present invention may be employed to “remove” the copper steps by planarizing the surface of such a substrate. Desirably, after performance of an exemplary process, the surface of the substrate will be planar, the planar surface including an uppermost surface of the interconnect structures at locations that were etched to form trenches and an uppermost surface of the insulating layer of the semiconductor substrate in locations that were not etched. Exemplary processes for polishing semiconductor substrates may include positioning a semiconductor substrate including a barrier layer and a copper layer as described above, polishing the positioned semiconductor substrate with a first polishing composition, and further polishing the polished semiconductor substrate with a second polishing composition. The mechanics of positioning and polishing the substrate may be performed as discussed above, or in other ways well known to those of ordinary skill in the art.

In conventional copper-based metal CMP processes, a first polishing composition is formulated to initially polish away all of the copper film, exposing the barrier layer and the formed copper interconnect structures. The conventional first polishing composition is not formulated to remove the barrier layer underlying the copper steps. A conventional second polishing composition is formulated remove the barrier layer exposed after polishing with the first polishing composition without removing exposed copper of the interconnect structures. To obtain a planar semiconductor substrate using conventional copper-based metal CMP processes, polishing with the first polishing composition must stop when upper surfaces of the interconnect structures have a height below a height of the barrier layer and are coplanar with a surface of the semiconductor substrate below the barrier layer. Accordingly, when the barrier layer is removed with the second polishing composition, the upper surface of the interconnect structures will be coplanar with the surface of the remaining semiconductor substrate. Obtaining such a precise relation between the height of the barrier layer and the height of the interconnect structures after polishing with the first polishing composition is extremely difficult.

By contrast, in various exemplary embodiments of the present invention, a first polishing composition is used to polish away much of the step structures, but leaving a thin layer of copper over the barrier layer and above the desired final upper surface of the interconnect structures. For example, after polishing with the first polishing composition, a film of copper having a thickness of about 2,000 angstroms may remain over the barrier layer and above the desired final upper surface of the interconnect structures. To achieve this result, first polishing compositions according to the present invention have a specific and novel formulation.

In embodiments, after polishing with the first polishing composition, further polishing is commenced with the second polishing composition. Exemplary second polishing compositions are formulated to remove the remaining thin layer of copper at a rate substantially the same or similar to a rate at which the underlying barrier layer is removed. After polishing with the second polishing composition, the upper surfaces of the interconnect structures are substantially coplanar with the upper surface of the insulating layer of the semiconductor substrate. To achieve this result, as with the first polishing compositions, second polishing compositions according to the present invention have a specific and novel formulation.

Possible formulations for exemplary polishing compositions according to the present invention are described below. While the formulations of polishing compositions are discussed collectively below, it should be appreciated that, when performing exemplary polishing processes according to the present invention, the first and second polishing compositions generally have different formulations.

In various exemplary embodiments, a copper-based metal polishing composition may include abrasive particles, a borate, an oxidizing agent, and a solvent. In various exemplary embodiments, the solvent is water.

Exemplary abrasive particles may include zirconium oxide particles. In embodiments, the abrasive particles may have a particle size of, for example, from 0.02 to 0.3 μm, preferably from 0.02 to 0.2 μm. Abrasive particles are present in the polishing composition in an amount of from 0.1 to 10% by weight, preferably from 0.5 to 5% by weight, relative to a total weight of the polishing composition.

In embodiments, borates employed in an exemplary copper-based metal polishing composition may include, for example, ammonium biborate, ammonium tetraborate, ammonium pentaborate, potassium biborate, potassium pentaborate, and mixtures thereof. Exemplary mixtures may include a combination of ammonium biborate and ammonium pentaborate, a combination of ammonium tetraborate and ammonium pentaborate, and/or a combination of potassium biborate and potassium pentaborate. In an exemplary copper-based metal polishing composition, borates may be present in an amount of from 0.5 to 10% by weight relative to a total weight of the polishing composition.

An exemplary oxidizing agent for use in a copper-based metal polishing composition may include hydrogen peroxide. In various exemplary embodiments, an oxidizing agent may be present in a polishing composition in an amount of from 0.05 to 5% by weight, preferably from 0.05 to 1% by weight, relative to a total weight of the polishing composition.

Exemplary copper-based metal polishing compositions may further include one or more organic acids. In embodiments, organic acids for use in exemplary copper-based metal polishing compositions may include citric acid, malic acid, nicotinic acid, gluconic acid, tartaric acid, and mixtures thereof. In an exemplary copper-based metal polishing composition, an organic acid may be present in an amount of from 0.05 to 3% by weight relative to a total weight of the polishing composition.

Exemplary copper-based metal polishing compositions may further include an amino acid. In embodiments, amino acids for use in exemplary copper-based metal polishing compositions may include glycine, alanine, isoleucine, leucine, valine, and mixtures thereof. In various exemplary embodiments, amino acids may be present in a copper-based metal polishing composition in an amount of from 0.001 to 10% by weight relative to a total weight of the polishing composition.

Exemplary copper-based metal polishing compositions may further include a pyrophosphate. In embodiments, pyrophosphates suitable for use in exemplary copper-based metal polishing compositions may include ammonium pyrophosphate, potassium pyrophosphate, and mixtures thereof. Pyrophosphates may be present in an exemplary copper-based metal polishing composition in an amount of from 0.5 to 10% by weight relative to a total weight of the polishing composition.

Exemplary copper-based metal polishing compositions may further include iodates. Exemplary iodates for inclusion in a copper-based metal polishing composition include ammonium iodate, potassium iodate, and mixtures thereof. In embodiments, iodates may be present in an exemplary copper-based metal polishing composition in an amount of from 0.5 to 10% by weight relative to a total weight of the polishing composition.

Exemplary copper-based metal polishing compositions may further include surfactants. Exemplary surfactants that may be included in a copper-based metal polishing composition may include sorbitan fatty acid esters such as sorbitan monolaurate, sorbitan monopalmitate, sorbitan monostearate, sorbitan monooleate, sorbitan trioleate, sorbitan tristearate and mixtures thereof. In various exemplary embodiments, surfactants may be present in a copper-based metal polishing composition in an amount of from 0.001 to 3% by weight relative to a total weight of the polishing composition.

In various exemplary embodiments, copper-based metal polishing compositions may further include organic dispersants. Exemplary organic dispersants for inclusion in a copper-based metal polishing composition may include cellulose, cellulose derivatives such as hydroxyalkyl celluloses, and mixtures thereof. In embodiments, organic dispersants may be present in a copper-based metal polishing composition in an amount of from 0.2 to 3% by weight relative to a total weight of the polishing composition.

Exemplary copper-based metal polishing compositions may further include anti-corrosive agents for copper. Exemplary anti-corrosive agents for copper may include benzotriazole, benzotriazole derivatives, and mixtures thereof. In various exemplary embodiments, anti-corrosive agents may be present in a copper-based metal polishing composition in an amount of from 0.0001 to 1% by weight, preferably from 0.0005 to 0.1% by weight, relative to a total weight of the polishing composition.

Exemplary copper-based metal polishing compositions may further include a preservative. Exemplary preservatives for inclusion in copper-based metal polishing compositions may include halogenated cyanoalkyl compounds, such as 2-dibromo-2,4-dicyanobutane, and mixtures of halogenated cyanoalkyl compounds. In embodiments, a preservative may be present in a copper-based metal polishing composition in an amount of from 0.001 to 3% by weight relative to a total weight of the polishing composition.

As discussed above, exemplary processes for polishing semiconductor substrates may include positioning a semiconductor substrate including a barrier layer and a copper layer as described above, polishing the positioned semiconductor substrate with a first polishing composition, and further polishing the polished semiconductor substrate with a second polishing composition. While first and second polishing compositions according the present invention may both have formulations as discussed above, when performing exemplary polishing processes according to the present invention, the first and second polishing compositions generally have different formulations. In various exemplary embodiments, the first polishing composition may include abrasive particles, an ammonium borate, an oxidizing agent, and water. The first polishing composition may have a pH of from 6.5 to 9, preferably from 7.5 to 8.5. In various exemplary embodiments, the pH of the first polishing composition is adjusted by adding ammonium hydroxide to the composition. In various exemplary embodiments, the second polishing composition may include abrasive particles, a potassium borate, an oxidizing agent, and water. In embodiments, the second polishing composition has a pH of from 7 to 10, preferably from 7.5 to 9.5. The pH of the second polishing composition may be adjusted by adding potassium hydroxide or ammonium hydroxide to the composition.

Exemplary formulations for the first and second polishing compositions are discussed separately below.

In various exemplary embodiments, first polishing compositions according to the present invention may include water as a solvent for other ingredients in the compositions.

In various exemplary embodiments, first polishing compositions according to the present invention may include an oxidizing agent. Exemplary oxidizing agents for use in exemplary first polishing compositions may include hydrogen peroxide. In embodiments, oxidizing agents may be present in the first polishing composition in an amount of from 0.05 to 5% by weight, preferably from 0.05 to 1% by weight, relative to a total weight of the first polishing composition. Presence of the oxidizing agent in the first polishing composition facilitates reaction of the polishing composition with a copper film.

In various exemplary embodiments, first polishing compositions according to the present invention may comprise a borate. In embodiments, the borate of the first polishing composition may include a mixture of ammonium pentaborate and ammonium tetraborate. In embodiments, the ammonium pentaborate and the ammonium tetraborate are present in the first polishing composition in a weight ratio of 5:1 or of about 5:1 (ammonium pentaborate:ammonium tetraborate). The presence of the borate in exemplary first polishing compositions confers on the solutions an ability to convert copper species at a surface of a copper film to facilitate efficient removal of the copper film by abrasive particles present in the first polishing composition.

In various exemplary embodiments, first polishing compositions according to the present invention may comprise ammonium phosphate, phenyl phosphoric acid, and their derivatives. The presence of ammonium phosphate in exemplary first polishing compositions improves the reactivity of the compositions with a copper film, without adversely affecting organic components that may also be present in the first polishing compositions.

In various exemplary embodiments, first polishing compositions according to the present invention may include sorbitan monolaurate. The presence of sorbitan monolaurate in first polishing compositions according to the present invention facilitates moderation of a reaction of the first polishing composition with a copper film. When combined with organic components that may be present in first polishing compositions, sorbitan monolaurate functions to substantially prevent scratching of a polished surface.

In various exemplary embodiments, first polishing compositions according to the present invention may include one or more amino acids. The presence of amino acids in first polishing compositions moderates a reaction of the first polishing compositions with a copper film. When combined with organic components that may be present in the first polishing composition, amino acids function to substantially prevent scratching of a polished surface.

In various exemplary embodiments, first polishing compositions according to the present invention may include an organic component. In embodiments, the organic component is 2-dibromo-2,4-dicyanobutane. When 2-dibromo-2,4-dicyanobutane is combined with amino acids and/or sorbitan monolaurate in exemplary first polishing compositions, the combination can facilitate substantial prevention of scratching of a polished surface.

In various exemplary embodiments, first polishing compositions according to the present invention may include a cellulose/water mixture. The cellulose/water mixture functions in exemplary first polishing compositions to evenly distribute abrasive particles present in the polishing compositions over a surface of a polishing pad.

In various exemplary embodiments, first polishing compositions according to the present invention may include ammonium hydroxide. In embodiments, ammonium hydroxide may be present in first polishing compositions in an amount of from 0 to 0.25% by weight relative to a total weight of the first polishing composition.

In various exemplary embodiments, first polishing compositions according to the present invention may include a mixture of benzotriazole and water. In embodiments, the mixture of benzotriazole and water may be present in the first polishing composition in an amount of from 0.0001 to 1% by weight, preferably from 0.0005 to 0.1% by weight, relative to a total weight of the first polishing composition. When present in an exemplary first polishing composition, the benzotriazole/water mixture functions to prevent staining during polishing. In addition, when combined with organic components that may be present in first polishing compositions, the benzotriazole/water mixture functions to substantially prevent scratching of a polished surface.

In various exemplary embodiments, second polishing compositions according to the present invention may include water as a solvent for other ingredients in the compositions.

In various exemplary embodiments, second polishing compositions according to the present invention may include an oxidizing agent. In embodiments, the oxidizing agent may include hydrogen peroxide. The oxidizing agent may be present in the second polishing composition in an amount of from 0.05 to 5% by weight, preferably from 0.05 to 1% by weight, relative to a total weight of the second polishing composition. Presence of an oxidizing agent in second polishing compositions facilitates reaction of the polishing compositions with a copper film.

In various exemplary embodiments, second polishing compositions according to the present invention may include potassium pyrophosphate. The presence of potassium pyrophosphate in exemplary second polishing compositions facilitates reaction of the polishing compositions with both a copper film and a barrier layer formed beneath the copper film on a semiconductor substrate.

In various exemplary embodiments, second polishing compositions according to the present invention may include potassium pentaborate. When present in second polishing compositions, potassium pentaborate functions to control reactivity of the second polishing compositions with a copper film while facilitating reaction of the second polishing compositions with a barrier layer. The presence of potassium pentaborate also prevents the second polishing compositions from reacting with a dielectric film underlying the copper film and the barrier layer.

In various exemplary embodiments, second polishing compositions according to the present invention may include potassium iodate. When present in exemplary second polishing compositions, potassium iodate functions to increase reactivity of the second polishing compositions with a barrier layer.

In various exemplary embodiments, second polishing compositions according to the present invention may include a mixture of lauraminoproprionic acid and sorbitan monolaurate. In embodiments, the mixture of lauraminoproprionic acid and sorbitan monolaurate may include lauraminoproprionic acid and sorbitan monolaurate in a ratio of 2:1 or of about 2:1 (lauraminoproprionic acid:sorbitan monolaurate). When present in exemplary second polishing compositions, the mixture of lauraminoproprionic acid and sorbitan monolaurate functions to facilitate removal of a copper film and a barrier layer at substantially the same rate by the second polishing compositions.

In various exemplary embodiments, second polishing compositions according to the present invention may include one or more amino acids. When present in exemplary second polishing compositions, the amino acids function to regulate reactivity of the second polishing compositions with a copper film, substantially reducing the possibility of defects due to copper staining.

In various exemplary embodiments, second polishing compositions according to the present invention may include 2-dibromo-2,4-dicyanobutane. When combined with amino acids and/or a mixture of lauraminoproprionic acid and sorbitan monolaurate that may be present in second polishing compositions, the combination of 2-dibromo-2,4-dicyanobutane, amino acids, and mixture of lauraminoproprionic acid and sorbitan monolaurate functions to substantially prevent scratching of a polished surface.

In various exemplary embodiments, second polishing compositions according to the present invention may include a cellulose/water mixture. When present in exemplary second polishing compositions, the cellulose/water mixture functions to evenly distribute abrasive particles in the second polishing composition over a surface of a polishing pad.

In various exemplary embodiments, second polishing compositions according to the present invention may include potassium hydroxide or ammonium hydroxide. In embodiments, the potassium hydroxide or ammonium hydroxide may be present in the first polishing composition in an amount of from 0 to 0.25% by weight relative to a total weight of the second polishing composition. An amount of potassium hydroxide or ammonium hydroxide employed in exemplary second polishing compositions may be varied to adjust a rate at which a barrier layer is removed based on a particular chemical composition of the barrier layer.

In various exemplary embodiments, second polishing compositions according to the present invention may include a mixture of benzotriazole and water. In embodiments, the mixture of benzotriazole and water may be present in the second polishing composition in an amount of from 0.0001 to 1% by weight, preferably from 0.0005 to 0.1% by weight, relative to a total weight of the second polishing composition. When present in an exemplary second polishing composition, the benzotriazole/water mixture functions to prevent staining during polishing. In addition, when combined with organic components that may be present in second polishing compositions, the benzotriazole/water mixture functions to substantially prevent scratching of a polished surface.

While first and second polishing compositions are described above, it should be appreciated that the compositions described above could be packaged or formulated as additive compositions for improving existing polishing compositions. That is, the compositions described above could be packaged or formulated without abrasive particles, as additive compositions that could be added, for example, to abrasive sols to obtain first and second polishing compositions as described above and/or to perform the processes described above.

### EXAMPLES

This invention is illustrated by the following examples, which are merely for the purpose of illustration.

Numerous Examples and Comparative Examples are prepared and tested to demonstrate the efficacy of first and second copper-based metal polishing compositions according to the present invention.

Additive compositions are prepared in 2500 g batches by mixing additive components in a 3000 ml HDPE mixing vessel using a bench-top mixer with a three-blade mixing propeller. The respective amounts of additive components are set forth in the tables below. Subsequent to preparation of the additive compositions, polishing compositions are prepared by adding the additive compositions and hydrogen peroxide water to a zirconia sol. The respective amounts of the polishing components are set forth in the formulation tables below.

In the formulation tables, T-Maz 28 is sorbitan monolaurate, Cellusize QP-300 is hydroxy ethyl cellulose, BTA is benzotriazole, and Tektamer 38 AD is 1,2-dibromo-2,4-dicyanobutane. Z-Sol is a zirconia sol having a primary particle size determined by the BET method of 43 nm, a secondary particle size determined by the laser diffraction method of 102 nm, and a secondary particle size determined by the laser scattering method of 125 nm. Z-Sol includes 20% by weight zirconium oxide.

### Example 1

| | |
|---|---|
| Component | wt % |

Additive

| | |
|---|---|
| Ammonium Pentaborate 8 H₂O | 3.855 |
| Ammonium Biborate 4 H₂O | 0.771 |
| Water | 95.374 |

Polishing Composition

| Component | wt part |
|---|---|
| Additive | 80 |
| Z-Sol | 20 |
| H₂O₂ (35%) | 0.50 |
| PH of Polishing Composition | 8.08 |

### Example 2

| | |
|---|---|
| Component | wt % |

Additive

| | |
|---|---|
| Ammonium Pentaborate 8 H₂O | 3.855 |
| Ammonium Biborate 4 H₂O | 0.771 |
| Citric Acid | 0.925 |
| Water | 94.449 |

Polishing Composition

| Component | wt part |
|---|---|
| Additive | 80 |
| Z-Sol | 20 |
| H₂O₂ (35%) | 0.50 |
| pH of Polishing Composition | 6.53 |

### Example 3

| | |
|---|---|
| Component | wt % |

Additive

| | |
|---|---|
| Ammonium Pentaborate 8 H₂O | 3.855 |
| Ammonium Biborate 4 H₂O | 0.771 |
| Serine | 0.925 |
| Water | 94.449 |

Polishing Composition

| Component | wt part |
|---|---|
| Additive | 80 |
| Z-Sol | 20 |
| H₂O₂ (35%) | 0.50 |
| pH of Polishing Composition | 7.92 |

### Example 4

| | |
|---|---|
| Component | wt % |

Additive

| | |
|---|---|
| Ammonium Pentaborate 8 H₂O | 3.855 |
| Ammonium Biborate 4 H₂O | 0.771 |
| Monoammonium Phosphate | 0.2 |
| Water | 95.174 |

Polishing Composition

| Component | wt part |
|---|---|
| Additive | 80 |
| Z-Sol | 20 |
| H₂O₂ (35%) | 0.50 |
| pH of Polishing Composition | 7.86 |

### Example 5

| | |
|---|---|
| Component | wt % |

Additive

| | |
|---|---|
| Ammonium Pentaborate 8 H₂O | 3.855 |
| Ammonium Biborate 4 H₂O | 0.771 |
| T-Maz 28 | 0.385 |
| Cellusize QP-300 (4% aqueous solution) | 15.4 |
| BTA (1% aqueous solution) | 0.1136 |
| Water | 79.4754 |

Polishing Composition

| | |
|---|---|
| Component | wt part |

| | |
|---|---|
| Additive | 80 |
| Z-Sol | 20 |
| H₂O₂ (35%) | 0.50 |
| pH of Polishing Composition | 7.99 |

### Example 6

| | |
|---|---|
| Component | wt % |

Additive

| | |
|---|---|
| Ammonium Pentaborate 8 H₂O | 3.855 |
| Ammonium Biborate 4 H₂O | 0.771 |
| Citric Acid | 0.925 |
| Glycine | 1.156 |
| T-Maz 28 | 0.385 |
| Cellusize QP-300 (4% aqueous solution) | 15.4 |
| BTA (1% aqueous solution) | 0.1136 |
| Water | 77.3024 |

Polishing Composition

| | |
|---|---|
| Component | wt part |

| | |
|---|---|
| Additive | 80 |
| Z-Sol | 20 |
| H₂O₂ (35%) | 0.50 |
| pH of Polishing Composition | 6.51 |

### Example 7

| | |
|---|---|
| Component | wt % |

Additive

| | |
|---|---|
| Potassium Pentaborate 8 H₂O | 2.04 |
| Water | 97.96 |

Polishing Composition

| Component | wt part |
|---|---|
| Additive | 90 |
| Z-Sol | 10 |
| H₂O₂ (35%) | 1.40 |
| ph of Polishing Composition | 8.01 |

### Example 8

| | |
|---|---|
| Component | wt % |

Additive

| | |
|---|---|
| Potassium Pentaborate 8 H₂O | 2.04 |
| Glycine | 2.04 |
| Water | 95.92 |

Polishing Composition

| Component | wt part |
|---|---|
| Additive | 90 |
| Z-Sol | 10 |
| H₂O₂ (35%) | 1.40 |
| ph of Polishing Composition | 7.92 |

### Example 9

| | |
|---|---|
| Component | wt % |

Additive

| | |
|---|---|
| Potassium Pentaborate 8 H₂O | 2.04 |
| Alanine | 2.04 |
| Water | 95.92 |

Polishing Composition

| Component | wt part |
|---|---|
| Additive | 90 |
| Z-Sol | 10 |
| H₂O₂ (35%) | 1.40 |
| ph of Polishing Composition | 8.01 |

### Example 10

| | |
|---|---|
| Component | wt % |

Additive

| | |
|---|---|
| Potassium Pentaborate 8 H₂O | 2.04 |
| Serine | 2.04 |
| Water | 95.92 |

Polishing Composition

| Component | wt part |
|---|---|
| Additive | 90 |
| Z-Sol | 10 |
| H₂O₂ (35%) | 1.40 |
| ph of Polishing Composition | 7.89 |

### Example 11

| | |
|---|---|
| Component | wt % |

Additive

| | |
|---|---|
| Potassium Pentaborate 8 H₂O | 2.04 |
| Tetrapotassium Pyrophosphate | 3.4 |
| Water | 94.56 |

Polishing Composition

| Component | wt part |
|---|---|
| Additive | 90 |
| Z-Sol | 10 |
| H₂O₂ (35%) | 1.40 |
| ph of Polishing Composition | 8.74 |

### Example 12

| | |
|---|---|
| Component | wt % |

Additive

| | |
|---|---|
| Potassium Pentaborate 8 H₂O | 2.04 |
| Potassium Iodate | 2.04 |
| Water | 95.92 |

Polishing Composition

| Component | wt part |
|---|---|
| Additive | 90 |
| Z-Sol | 10 |
| H₂O₂ (35%) | 1.40 |
| ph of Polishing Composition | |

### Example 13

| | |
|---|---|
| Component | wt % |

Additive

| | |
|---|---|
| Potassium Pentaborate 8 H₂O | 2.04 |
| T-Maz 28 | 0.01 |
| Cellusize QP-300 (4% aqueous solution) | 13.6 |
| BTA (1% aqueous solution) | 2.5 |
| Water | 81.85 |

Polishing Composition

| | |
|---|---|
| Component | wt part |

| | |
|---|---|
| Additive | 90 |
| Z-Sol | 10 |
| H₂O₂ (35%) | 1.40 |
| ph of Polishing Composition | 8.09 |

### Example 14

| | |
|---|---|
| Component | wt % |

Additive

| | |
|---|---|
| Potassium Pentaborate 8 H₂O | 2.04 |
| Glycine | 2.04 |
| T-Maz 28 | 0.01 |
| Cellusize QP-300 (4% aqueous solution) | 13.6 |
| Tektamer 38AD | 0.081 |
| BTA (1% aqueous solution) | 2.5 |
| Water | 79.729 |

Polishing Composition

| | |
|---|---|
| Component | wt part |

| | |
|---|---|
| Additive | 80 |
| Z-Sol | 20 |
| H₂O₂ (35%) | 1.40 |
| ph of Polishing Composition | 7.96 |

### Example 15

| | |
|---|---|
| Component | wt % |

Additive

| | |
|---|---|
| Ammonium Pentaborate 8 H₂O | 3.855 |
| Citric Acid | 0.925 |
| Water | 95.22 |

Polishing Composition

| | |
|---|---|
| Component | wt part |

| | |
|---|---|
| Additive | 80 |
| Z-Sol | 20 |
| H₂O₂ (35%) | 0.50 |
| ph of Polishing Composition | 7.5 |

### Example 16

| | |
|---|---|
| Component | wt % |

Additive

| | |
|---|---|
| Ammonium Pentaborate 8 H₂O | 3.855 |
| Ammonium Biborate 4 H₂O | 0.771 |
| Citric Acid | 94.449 |
| Water | 94.449 |

Polishing Composition

| | |
|---|---|
| Component | wt part |

| | |
|---|---|
| Additive | 80 |
| Z-Sol | 20 |
| H₂O₂ (35%) | 0.50 |
| ph of Polishing Composition | 6.57 |

### Example 17

| | |
|---|---|
| Component | wt % |

Additive

| | |
|---|---|
| Potassium Biborate 4 H₂O | 0.771 |
| Glycine | 2.04 |
| Water | 97.189 |

Polishing Composition

| | |
|---|---|
| Component | wt part |

| | |
|---|---|
| Additive | 90 |
| Z-Sol | 10 |
| H₂O₂ (35%) | 1.40 |
| ph of Polishing Composition | 8.78 |

### Example 18

| | |
|---|---|
| Component | wt % |

Additive

| | |
|---|---|
| Potassium Biborate 4 H₂O | 0.771 |
| Potassium Pentaborate 8 H₂O | 2.04 |
| Glycine | 2.04 |
| Water | 95.149 |

Polishing Composition

| | |
|---|---|
| Component | wt part |

| | |
|---|---|
| Additive | 90 |
| Z-Sol | 10 |
| H₂O₂ (35%) | 1.40 |
| ph of Polishing Composition | 8.40 |

### Comparative Example 1

| | |
|---|---|
| Component | wt % |

Additive

| | |
|---|---|
| Citric Acid | 1 |
| Glycine | 1 |
| Water | 98 |

Polishing Composition

| | |
|---|---|
| Component | wt part |

| | |
|---|---|
| Additive | 80 |
| Z-Sol | 20 |
| H₂O₂ (35%) | 0.50 |
| ph of Polishing Composition | 2.87 |

### Comparative Example 2

| | |
|---|---|
| Component | wt % |

Additive

| | |
|---|---|
| Glycine | 1 |
| TKPP | 3 |
| Water | 96 |

Polishing Composition

| | |
|---|---|
| Component | wt part |

| | |
|---|---|
| Additive | 80 |
| Z-Sol | 20 |
| H₂O₂ (35%) | 0.50 |
| ph of Polishing Composition | 9.16 |

### Comparative Example 3

| | |
|---|---|
| Component | wt % |

Additive

| | |
|---|---|
| Glycine | 2.04 |
| T-Maz 28 | 0.01 |
| Cellusize QP-300 (4% aqueous solution) | 13.6 |
| Tektamer 38AD | 0.081 |
| BTA (1% aqueous solution) | 2.5 |
| Water | 81.769 |

Polishing Composition

| | |
|---|---|
| Component | wt part |

| | |
|---|---|
| Additive | 80 |
| Z-Sol | 20 |
| H₂O₂ (35%) | 0.50 |
| ph of Polishing Composition | 4.66 |

Each of the slurry compositions described in the tables above is used to polish at least one test wafer (a copper blanket test wafer and/or a copper pattern test wafer). Polishing is carried out with a polisher under 3 psi with a table speed of 50 rpm and a carrier speed of 50 rpm. A condition cycle of 20 seconds is carried out using a 125 μm disc. A 10 second de-chuck water rinse cycle follows. A slurry flow rate of 100 ml/min is employed. Blanket test wafers are subjected to a single polishing cycle. Pattern test wafers are subjected to one or two polishing cycles.

The tests performed for each formulation can be seen in the results table below. Blanket test wafers are evaluated to determine a copper removal rate for the respective slurry formulations. Evaluation of removal rate is carried out by performing a polishing cycle on a blanket test wafer and measuring a copper layer thickness of the blanket test wafer both before and after the polishing cycle (e.g., with a sheet resistance meter). A difference in copper layer thickness is measured and from the measured value, a copper removal rate is determined. After performing a polishing cycle, blanket test wafers are also evaluated for staining. Evaluation for staining involves a subjective visual inspection for surface irregularities, such as non-reflective areas, cloudy areas, etc.

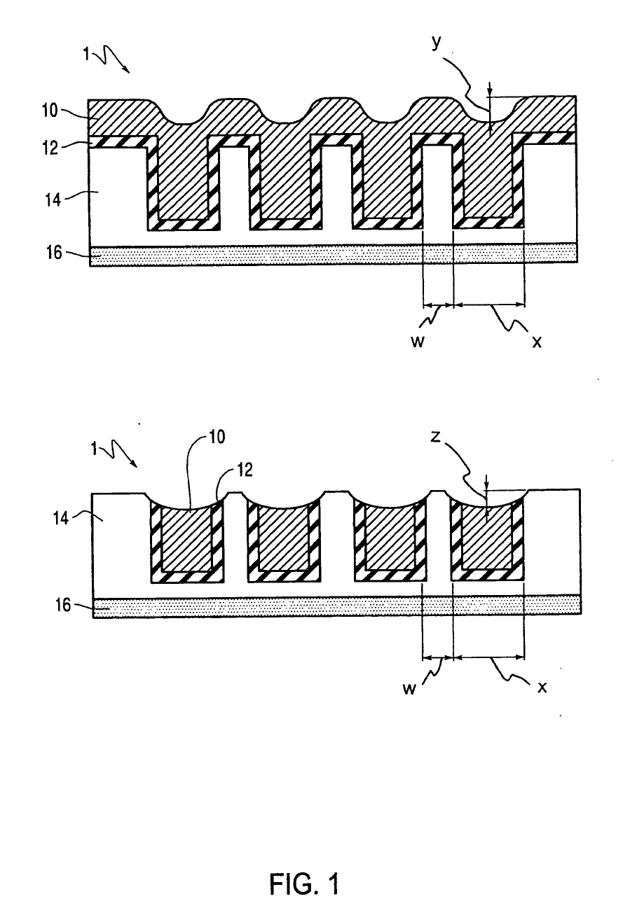

After a first polishing cycle, pattern test wafers are likewise evaluated to determine an amount of copper removed and a copper removal rate, and an inspection for staining is conducted. Pattern test wafers are also evaluated to determine an amount of dishing after a first polishing cycle. Dishing refers to excessive, unwanted removal of metal (e.g., copper) from metal interconnect precursors during CMP. The excess removal of metal results in unwanted cavities in an interconnect structure. Dishing is undesirable because it negatively affects electrical performance of a resulting semiconductor structure (e.g., integrated circuit). FIG. 1 shows a schematic depiction of a patterned wafer 1 in which dishing has occurred after a first polishing step and a second polishing step. The patterned wafer 1 includes a silicon substrate 16, a silicon oxide layer 14 including etched trenches formed over the silicon substrate 16, a tantalum barrier layer 12 formed over the silicon oxide layer 14, and a copper layer 10 formed over the tantalum barrier layer 12. The etched trenches in the silicon oxide layer 14 are formed so that the trenches have a width x and the remaining silicon oxide portions separating the trenches have a width w. Dishing after a first polishing step is exemplified by cavities having a depth y formed in the copper layer 10, which is desirably planar after the first polishing step. Dishing after a second polishing step is exemplified by cavities having a depth z, which extend into the patterned wafer 1 below an uppermost surface of the silicon oxide layer 14. Desirably, after the second polishing step, the uppermost surface of the silicon oxide layer 14 and the uppermost layer of the copper layer 10 will be coplanar.

Dishing of pattern test wafers is evaluated by measuring (e.g., with a profilometer) dishing of 100 μm lines in the center, middle and edge of the pattern test wafers. In some Examples, dishing of pattern test wafers is again evaluated after a second polishing cycle. Planarization efficiency is also evaluated. Planarization efficiency is evaluated by comparing copper removal rates between areas on the pattern test wafer having features and areas on the pattern test wafer not having features. Planarization efficiency is expressed by:

Planarization efficiency=Step height reduction/Removed thickness

Step height reduction refers to an amount by which a difference in thickness (“step”) of the copper layer between an area on the pattern test wafer having a feature and an area on the pattern test wafer not having the feature is reduced by polishing. Removed thickness refers to an amount by which the thickness of the copper layer in the area on the pattern test wafer not having the feature is reduced by polishing. Ideally, the planarization efficiency is as close to 1 as possible—so that the copper layer has a planar surface over areas including and not including features. While the planarization efficiency value theoretically does not exceed 1, due to imprecision resulting from the resolution of equipment used to measure the parameters used to calculate planarization ratio, planarization ratios of more than 1 can be obtained (see, e.g., Example 6 below).

The evaluation results are set forth in the table below.

| | | | | Patterned | | | | |
|---|---|---|---|---|---|---|---|---|
| | | | Patterned | Wafer | | Patterned | | Patterned |
| | Blanket | | Wafer | First | Patterned | Wafer | | Wafer |
| | Wafer Cu | | First | Polish Cu | Wafer | First | | Second |
| | Removal | Blanket | Polish Cu | Removal | First | Polish | | Polish |
| | Rate | Wafer | Removed | Rate | Polish | Dishing | Planarization | Dishing |
| Example | (Å/min) | Staining | (Å) | (Å/min) | Staining | (Å) | Efficiency | (Å) |
| E1 | 5900 | No | 4950 | 6600 | No | 1205 | 0.77 | — |
| E2 | 5850 | No | 4650 | 6200 | No | 1107 | 0.84 | — |
| E3 | 6100 | No | 5025 | 6032 | No | 1341 | 0.73 | — |
| E4 | 6075 | No | 5060 | 6075 | No | 1285 | 0.73 | — |
| E5 | 1925 | No | 4975 | 2297 | No | 450 | 0.91 | — |
| E6 | 900 | No | 4800 | 1200 | No | 105 | 1.02 | — |
| E7 | 225 | No | — | — | — | — | — | — |
| E8 | 12925 | No | — | — | — | — | — | — |
| E9 | 4525 | No | — | — | — | — | — | — |
| E10 | 7950 | No | — | — | — | — | — | — |
| E11 | 4800 | No | — | — | — | — | — | — |
| E12 | 380 | No | — | — | — | — | — | — |
| E13 | 350 | No | — | — | — | — | — | — |
| E14 | 1150 | No | 2500 | 1250 | No | 300 | — | 250 |
| E15 | 7616 | No | 5100 | 6800 | No | 1500 | 0.69 | — |
| E16 | 5966 | No | 5000 | 5555 | No | 1072 | 0.79 | — |
| E17 | 15300 | No | — | — | — | — | — | — |
| E18 | 15400 | No | — | — | — | — | — | — |
| CE1 | 1283 | No | — | 1488 | No | 1500 | 0.77 | — |
| CE2 | 6233 | Yes | — | 5433 | Yes | 1137 | 0.77 | — |
| CE3 | 600 | No | 1800 | 2300 | No | 300 | — | 1000 |

The above Examples demonstrate that first and second polishing compositions according to the present invention are effective for conducting copper-based metal CMP. The Examples further illustrate that the various components of first and second polishing compositions according to the present invention can be tuned to optimize performance of the resulting compositions. Also, comparison of Example 14 and Comparative Example 3 illustrates that a significant reduction in dishing is achieved by the polishing compositions according to the present invention relative to conventional polishing compositions (“Patterned Wafer Second Polish Dishing” of CE 3 is 1000 Å, while E14 is 250 Å). This reduction can be attributed to the presence of borates in the polishing compositions according to the present invention, and the absence of such borates in conventional compositions.

While this invention has been described in conjunction with the exemplary embodiments outlined above, various alternatives, modifications, variations, improvements and/or substantial equivalents, whether known or that are or may be presently unforeseen, may become apparent to those having at least ordinary skill in the art. Accordingly, the exemplary embodiments of the invention, as set forth above, are intended to be illustrative, not limiting. Various changes may be made without departing from the spirit and scope of the invention. Therefore, the invention is intended to embrace all known or later developed alternatives, modifications, variations, improvements and/or substantial equivalents.

What is claimed is:

1. A copper-based metal polishing composition, comprising abrasive particles, a borate, an oxidizing agent, and water.

2. The polishing composition according to claim 1, wherein:
the abrasive particles comprise zirconium oxide particles having a particle diameter of from 0.02 to 0.3 μm; and
the abrasive particles are present in the polishing composition in an amount of from 0.1 to 10% by weight relative to a total weight of the polishing composition.

3. The polishing composition according to claim 1, wherein:
the borate is selected from the group consisting of ammonium biborate, ammonium tetraborate, ammonium pentaborate, potassium biborate, potassium pentaborate, a combination of ammonium biborate and ammonium pentaborate, a combination of ammonium tetraborate and ammonium pentaborate, and a combination of potassium biborate and potassium pentaborate;
the borate is present in the polishing composition in an amount of from 0.5 to 10% by weight relative to a total weight of the polishing composition.

4. The polishing composition according to claim 1, wherein:
the oxidizing agent comprises hydrogen peroxide; and
the oxidizing agent is present in the polishing composition in an amount of from 0.05 to 5% by weight relative to a total weight of the polishing composition.

5. The polishing composition according to claim 1, further comprising an organic acid.

6. The polishing composition according to claim 5, wherein:
the organic acid is selected from the group consisting of citric acid, malic acid, nicotinic acid, gluconic acid, tartaric acid, and mixtures thereof; and
the organic acid is present in the polishing composition in an amount of from 0.05 to 3% by weight relative to a total weight of the polishing composition.

7. The polishing composition according to claim 1, further comprising an amino acid.

8. The polishing composition according to claim 7, wherein:
the amino acid is selected from the group consisting of glycine, alanine, isoleucine, leucine, valine, and mixtures thereof; and
the amino acid is present in the polishing composition in an amount of from 0.001 to 10% by weight relative to a total weight of the polishing composition.

9. The polishing composition according to claim 1, further comprising a pyrophosphate.

10. The polishing composition according to claim 9, wherein:
the pyrophosphate is selected from the group consisting of ammonium pyrophosphate, potassium pyrophosphate, and mixtures thereof; and
the pyrophosphate is present in the polishing composition in an amount of from 0.5 to 10% by weight relative to a total weight of the polishing composition.

11. The polishing composition according to claim 1, further comprising an iodate.

12. The polishing composition according to claim 11, wherein:
the iodate is selected from the group consisting of ammonium iodate, potassium iodate, and mixtures thereof; and
the iodate is present in the polishing composition in an amount of from 0.5 to 10% by weight relative to a total weight of the polishing composition.

13. The polishing composition according to claim 1, further comprising a surfactant.

14. The polishing composition according to claim 13, wherein:
the surfactant comprises one or more sorbitan fatty acid esters selected from the group consisting of sorbitan monolaurate, sorbitan monopalmitate, sorbitan monostearate, sorbitan monooleate, sorbitan trioleate and sorbitan tristearate; and
the surfactant is present in the polishing composition in an amount of from 0.001 to 3% by weight relative to a total weight of the polishing composition.

15. The polishing composition according to claim 1, further comprising an organic dispersant.

16. The polishing composition according to claim 15, wherein:
the organic dispersant is selected from the group consisting of cellulose, cellulose derivatives, and mixtures thereof; and
the organic dispersant is present in the polishing composition in an amount of from 0.2 to 3% by weight relative to a total weight of the polishing composition.

17. The polishing composition according to claim 1, further comprising an anti-corrosive agent for copper.

18. The polishing composition according to claim 17, wherein:
the anti-corrosive agent for copper is selected from the group consisting of benzotriazole, benzotriazole derivatives, and mixtures thereof; and
the anti-corrosive agent is present in the polishing composition in an amount of from 0.0001 to 1% by weight relative to a total weight of the polishing composition.

19. The polishing composition according to claim 1, further comprising a preservative.

20. The polishing composition according to claim 19, wherein:
the preservative is selected from the group consisting of halogenated cyanoalkyl compounds, and mixtures thereof; and
the preservative is present in the polishing composition in an amount of from 0.001 to 3% by weight relative to a total weight of the polishing composition.

21. The polishing composition according to claim 1, wherein:
the borate is an ammonium borate; and
the polishing composition has a pH of from 6.5 to 9, the pH being adjusted by addition of ammonium hydroxide to the polishing composition.

22. The polishing composition according to claim 21, wherein the polishing composition has a pH of from 7.5 to 8.5.

23. The polishing composition according to claim 1, wherein:
the borate is a potassium borate; and
the polishing composition has a pH of from 7 to 10, the pH being adjusted by addition of potassium hydroxide or ammonium hydroxide to the polishing composition.

24. The polishing composition according to claim 23, wherein the polishing composition has a pH of from 7.5 to 9.5.

25. A process for polishing a semiconductor substrate, comprising:
positioning the semiconductor substrate, a surface of the semiconductor substrate having a barrier layer formed thereon and the barrier layer having a copper layer formed thereon;
polishing the positioned semiconductor substrate with a first polishing composition, the first polishing composition comprising abrasive particles, an ammonium borate, an oxidizing agent, and water, the first polishing composition having a pH of from 6.5 to 9, the pH being adjusted by addition of ammonium hydroxide to the first polishing composition; and
further polishing the polished semiconductor substrate with a second polishing composition, the second polishing composition comprising abrasive particles, a potassium borate, an oxidizing agent, and water, the second polishing composition having a pH of from 7 to 10, the pH being adjusted by addition of potassium hydroxide or ammonium hydroxide to the second polishing composition.
